(19) United States
(12) Patent Application Publication
(10) Pub. No.: US 2005/0266661 A1
(43) Pub. Date: Dec. 1, 2005

(54) Semiconductor wafer with ditched scribe street

(76) Inventors: Lei Li, Richardson, TX (US); Vish Sundararaman, Plano, TX (US); Margaret Simmons-Matthews, Richardson, TX (US)

Correspondence Address: TEXAS INSTRUMENTS INCORPORATED, P O BOX 655474, M/S 3999, DALLAS, TX, 75265, US

(21) Appl. No.: 10/853,812

(22) Filed: May 26, 2004

(51) Int. Cl. H01L 21/301

(52) U.S. Cl. 438/462

(57) ABSTRACT

A semiconductor wafer (10) and associated methods are disclosed in which a plurality of semiconductor dice (14) include a semiconductor substrate (12) overlain by a plurality of upper layers (13) are provided with encompassing scribe streets (20) at the top surface (16) of the wafer (10) defined by inactive areas (18) between and circumscribing the dice (14). Ditches (22) in the scribe streets (20) extend from the top surface (16) to the substrate (12) for facilitating saw singulation of the dice (14).

### TECHNICAL FIELD

The invention relates in general to semiconductors devices and to semiconductor devices manufacturing. More particularly, it relates to semiconductor wafers with ditched scribe streets for facilitating chip singulation, and methods for manufacturing the same.

### BACKGROUND OF THE INVENTION

It is common to form semiconductor devices, or chips, in large quantities arrayed on the upper surface of a semiconductor wafer. The chips are fashioned with multiple layers of conductive and non-conductive materials interconnected to form circuitry. The completed chips are typically singulated for final packaging by cutting the wafer at gaps of inactive area left between and around the active areas of the chips for that purpose. Mechanical sawing is the process generally used for singulation.

Mechanically sawing through a multi-layered semiconductor wafer presents certain problems. For example, instances of chipping, cracking, or peeling of the multiple layers of the completed wafer are not uncommon. This type of damage is often caused by the stresses induced by sawing the inactive areas and can cause damage to the adjacent active areas. The result may be reduced yield, defective devices, increased inspection and testing requirements, and increased expense. Examples of efforts to minimize such problems include: Providing wider inactive areas, at the expense of smaller active areas, and; laser cutting, often in combination with mechanical sawing, with the expense of additional equipment and additional processing time. These examples of problems encountered in wafer sawing may be particularly acute with the fabrication of devices employing copper film as a conductive interconnect material and low-k or ultra low-k dielectric materials.

Due to these and other problems, improved wafers and methods for facilitating the avoidance of damage to devices upon singulation would be useful and desirable in the arts.

### SUMMARY OF THE INVENTION

In carrying out the principles of the present invention, in accordance with preferred embodiments thereof, methods and devices are provided in which the chips on a semiconductor wafer are circumscribed by ditched scribe streets to facilitate sawing.

According to one aspect of the invention, a method for manufacturing a semiconductor wafer having a plurality of semiconductor chips includes steps of applying photo resist material to the top surface of the wafer to protect the chips, and forming a pattern of scribe streets adjacent to the chip edges. In a further step, ditches are etched into the scribe streets extending from the wafer surface down to the substrate below the multiple layers of conductive and non-conductive materials.

According to another aspect of the invention, a method for singulating semiconductor chips from a wafer includes steps for applying photo resist material to the top surface of the wafer to protect the chips. A pattern of scribe streets is formed adjacent to the chip edges by removing selected portions of the photo resist. The scribe streets are etched to form ditches extending from the wafer surface to the substrate below the multiple layers of conductive and non-conductive materials. In a further step, the wafer is sawn in alignment with the ditches in order to singulate the semiconductor chips.

According to additional aspects of the invention, examples of preferred embodiments of semiconductor wafers of the invention include a semiconductor wafer with numerous semiconductor chips arranged thereon. The wafer has a semiconductor substrate overlain by a series of upper layers. A scribe street at the top surface of the wafer is defined by inactive areas between and surrounding the edges of the chips. A ditch in the scribe street extends from the top surface of the wafer to the semiconductor substrate below the multiple layers of conductive and non-conductive materials.

According to still another aspect of the invention, examples of specific embodiments include wafers and associated manufacturing methods of the invention for providing a scribe street ditch within the range of approximately 40 to 90 um in width in inactive areas circumscribing the chips on the wafer.

According to yet another aspect of the invention, examples of specific embodiments include wafers and associated methods of the invention providing a scribe street ditch within the range of approximately 10 to 40 um in depth in the inactive areas bordering the chips on the wafer.

The invention provides technical advantages including but not limited to higher yield of devices undamaged by the sawing operation, savings of time providing improved throughput for reduced-damage singulation methods, lower manufacturing costs, and advantageous extension of existing manufacturing processes. These and other features, advantages, and benefits of the present invention can be understood by one of ordinary skill in the art upon careful consideration of the detailed description of representative embodiments of the invention in connection with the accompanying drawings.

### BRIEF DESCRIPTION OF THE DRAWINGS

The present invention will be more clearly understood from consideration of the following detailed description and drawings in which:

FIG. 1 is a top perspective view of a semiconductor wafer illustrating an example of an embodiment of the invention having semiconductor chips with ditched scribe streets;

FIG. 2A is a partial cross section view of a semiconductor wafer showing an example of steps in preferred method embodiments of the invention;

FIG. 2B is a partial cross section view of a semiconductor wafer showing an example of preferred embodiments of the invention; and

FIG. 3 is a process flow diagram showing an alternative view of steps in an example of preferred methods according to the invention.

References in the detailed description correspond to like references in the figures unless otherwise noted. Descriptive and directional terms used in the written description such as first, second, top, bottom, upper, side, etc., refer to the drawings themselves as laid out on the paper and not to physical limitations of the invention unless specifically noted. The drawings are not to scale, and some features of embodiments shown and discussed are simplified or amplified for illustrating the principles, features, and advantages of the invention.

### DETAILED DESCRIPTION OF PREFERRED EMBODIMENTS

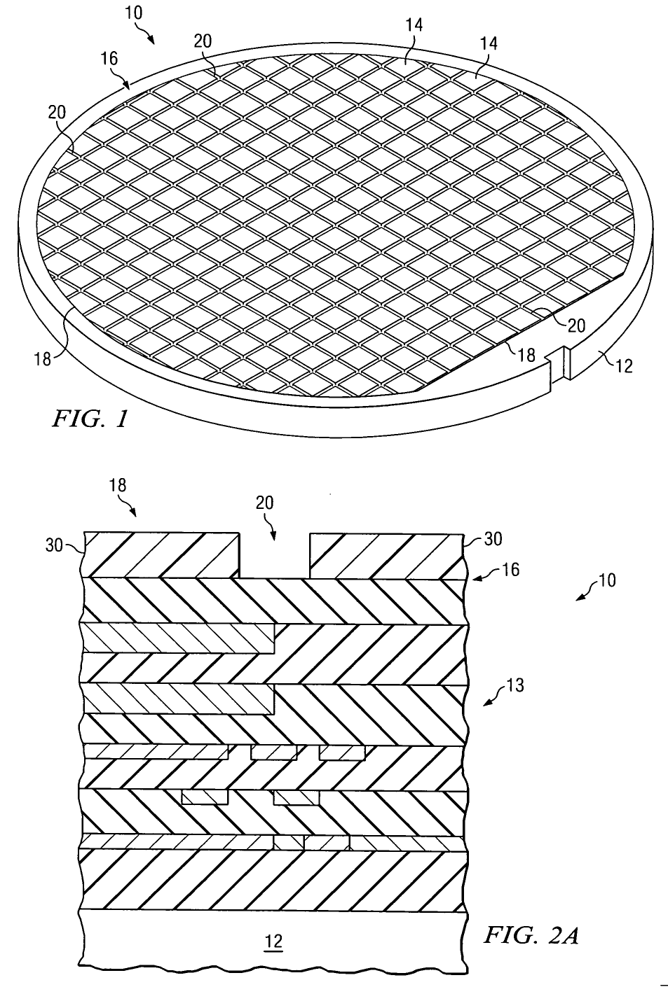

In general, the methods and devices of the invention provide improved semiconductor wafers providing features for improving singulation of individual devices. An example of a preferred embodiment of a semiconductor wafer of the invention is illustrated in the top perspective view of FIG. 1. The wafer 10, preferably has a semiconductor substrate 12 such as silicon, although other materials are sometimes used. The substrate 12 is typically overlain by various layers 13 of interconnected conductive and non-conductive materials in order to implement microelectronic circuitry in numerous chips 14 arranged on the top surface 16 of the wafer 10. Typically, semiconductor wafers 10 with chips 14 formed thereon have inactive areas 18 around the edges of the chips 14 in order to provide a margin for manufacturing purposes. The inactive area 18 preferably more or less defines the boundaries of a scribe street 20. The wafer 10 may be sawn along the scribe street 20 in order to separate the chips 14 for individual packaging and use. The scribe street 20 on wafers 10 of the invention includes a ditch 22, along which the wafer 10 may be sawn. Preferably, the scribe street 20 extends from the top surface 16 of the wafer to the substrate layer 12 below the multiple layers of conductive and non-conductive materials. It has been found that the scribe street ditch 22 is effective in preventing damage such as chipping and cracking to the chip 14 edges. Preferably, the sides of the ditch 22 are approximately 10 um from the edge of the inactive area 18 of the chips 14, permitting the edges of the ditch 22 to be relatively coarse without detriment to the functioning of the chips 14.

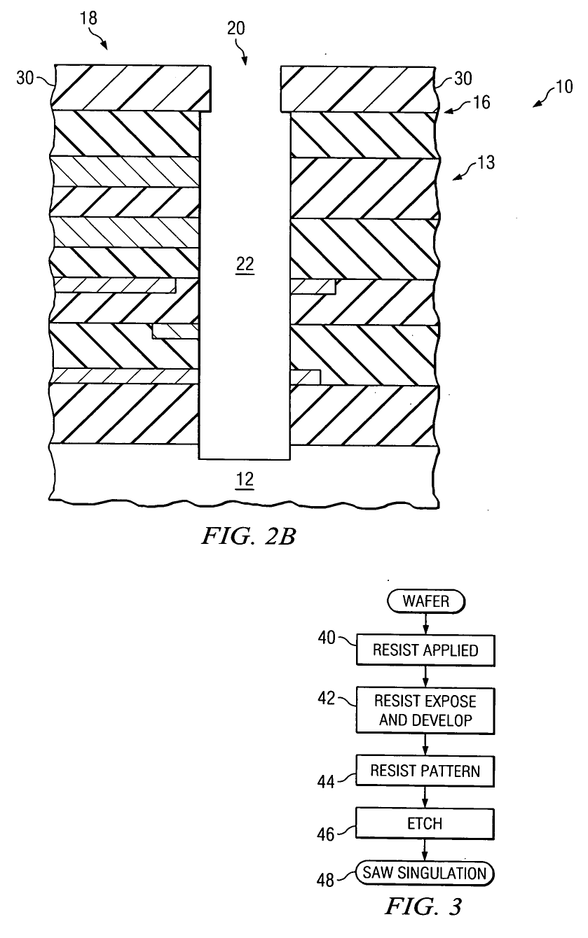

The ditches 22 are preferably formed using traditional manufacturing processes. Close-up views of the inactive areas 18 of the wafer 10 are shown and further described referring primarily to FIGS. 2A and 2B. The wafer 10 is preferably manufactured according to ordinary manufacturing methods known in the arts up to a point approaching the singulation process. The new steps for implementing the invention are preferably performed after the chips are substantially completed, and prior to singulation. Preferably, ordinary manufacturing processes and equipment are used to add the new steps according to the invention. Now referring primarily to FIG. 2A, the top surface 16 of the wafer 10 is covered with a photo resist material 30. The photo resist 30 is developed and patterned to define scribe streets 20 on the inactive areas 18 adjacent to the chip 14 edges. The exposed scribe streets 20 are then etched, preferably using common wet or dry etching techniques, in order to form ditches 22 as shown in FIG. 2B. Preferably, the ditches 22 are formed leaving about 10 um of inactive area material 18 between the sides of the ditches 22 and the active areas of the chips 14. Accordingly, the width of the ditches 22 may generally be between about 50 um and 90 um, although other widths may also be used without departure from the invention. Preferably the ditch 22 is of a width greater than the width of the saw blade to ultimately be used for singulation of the individual chips 14. The ditch 22 preferably extends down from the wafer surface 16 to the wafer substrate 12 below the multiple layers of conductive and non-conductive materials, thus providing maximum assurance that the devices 14 will not subjected to potential damage by the stresses induced by singulation. A ditch 22 depth of approximately 10 um to 40 um is generally sufficient, although a greater or lesser depth may be used according to specific application requirements.

Ultimately, the individual chips 14 are singulated by aligning a cutting tool, such as a mechanical saw, with the ditches 22 and sawing through the exposed substrate 12. FIG. 3 presents an alterative depiction of the process flow of steps of preferred embodiments of the invention. A wafer 10, preferably prepared by conventional processes, has substantially completed processing the chips thereon, typically with a passivation overcoat in preparation for chip singulation and packaging. As shown at step 40, photo-resist material is applied, preferably using conventional spin-coating techniques. The photo-resist is developed 42 and the desired pattern for the scribe street ditches is determined and transferred to the photo-resist material, shown in step 44. The ditches are etched 46 into the wafer, preferably using wet or dry etching techniques familiar in the arts. Subsequently, chip singulation is performed 48, preferably using common mechanical sawing processes, by slicing the wafer in alignment with the ditches. It will be appreciated by those skilled in the arts that other steps may be interposed between the etching step 46 and chip singulation 48, such as for example, cleaning, ashing, or transferring the wafer to a packaging facility.

Thus, the invention provides new semiconductor wafers and methods for making the same, as well as methods for chip singulation. Ditched scribe streets are provided for improved singulation of individual chips. The methods and devices of the invention provide advantages including but not limited to a higher yield of devices undamaged by sawing, improved throughput for reduced-damage singulation methods, lower manufacturing costs, and extension of existing manufacturing processes. While the invention has been described with reference to certain illustrative embodiments, the methods and apparatus described are not intended to be construed in a limited sense. Various modifications and combinations of the illustrative embodiments as well as other advantages and embodiments of the invention will be apparent to persons skilled in the art upon reference to the description and claims.

1. A method for manufacturing semiconductor chips comprising the steps of:
providing a wafer including a semiconductor substrate and layers of conductive and non-conductive materials extending outwardly from the top of the semiconductor substrate;
applying photo resist material to the top surface of the wafer;
removing selected portions of the photo resist to form a pattern of scribe streets adjacent to the edges of the chips;
etching the scribe streets to remove the layers of conductive and non-conductive materials to form ditches extending from the wafer surface to the semiconductor substrate; and
sawing through the semiconductor portion of the wafer along the scribe streets.

2. The method according to claim 1 wherein the etching step further comprises etching ditches greater than approximately 50 um in width.

3. The method according to claim 1 wherein the etching step further comprises etching ditches less than approximately 90 um in width.

4. The method according to claim 1 wherein the etching step further comprises etching ditches within the range of approximately 50 to 90 um in width.

5. The method according to claim 1 wherein the etching step further comprises etching ditches greater than approximately 10 um in depth.

6. The method according to claim 1 wherein the etching step further comprises etching ditches less than approximately 40 um in depth.

7. The method according to claim 1 wherein the etching step further comprises etching ditches within the range of approximately 10 to 40 um in depth.

8. A method for singulating semiconductor chips from a wafer containing a plurality of semiconductor chips, the method comprising the steps of:
providing a wafer including a semiconductor substrate and layers of conductive and non-conductive materials extending outwardly from the top of the semiconductor substrate;
applying photo resist material to the top surface of the wafer;
removing selected portions of the photo resist to form a pattern of scribe streets adjacent to the edges of the chips;
etching the scribe streets to remove the layers of conductive and non-conductive materials to form ditches extending from the wafer surface to the semiconductor substrate; and
sawing through the remaining semiconductor substrate in alignment with the ditches to form singulated semiconductor chips.

9. The method for singulating semiconductor chips from a wafer according to claim 8 wherein the etching step further comprises etching ditches greater than approximately 40 um in width.

10. The method for singulating semiconductor chips from a wafer according to claim 8 wherein the etching step further comprises etching ditches less than approximately 90 um in width.

11. The method for singulating semiconductor chips from a wafer according to claim 8 wherein the etching step further comprises etching ditches within the range of approximately 40 to 90 um in width.

12. The method for singulating semiconductor chips from a wafer according to claim 8 wherein the etching step further comprises etching ditches greater than approximately 10 um in depth.

13. The method for singulating semiconductor chips from a wafer according to claim 8 wherein the etching step further comprises etching ditches less than approximately 40 um in depth.

14. The method for singulating semiconductor chips from a wafer according to claim 8 wherein the etching step further comprises etching ditches within the range of approximately 10 to 40 um in depth.

15-23. (canceled)

24. The method of claim 1, in which the non-conductive layers include low-K dielectric material.

25. The method of claim 1, in which the conductive layers include copper.

26. The method of claim 1, in which the semiconductor substrate includes silicon.

27. The method of claim 8, in which the non-conductive layers include low-K dielectric material.

28. The method of claim 8, in which the conductive layers include copper.

29. The method of claim 8, in which the semiconductor substrate includes silicon.
